(19) United States
(12) Patent Application Publication
(10) Pub. No.: US 2006/0205176 A1
(43) Pub. Date: Sep. 14, 2006

(54) Method for producing a component, body for producing a component of this type and component produced according to said method

(75) Inventors: Jochen Butzek, Jona (CH); Frank Ehrig, Jona (CH); Norbert Ahlborn, Zurich (CH); Wolf-Dieter Vogel, Bad Heilbrunn (DE); Klaus Dilger, Aachen (DE); Jan-Dirk Reimers, Aachen (DE)

Correspondence Address: SUGHRUE MION, PLLC, 2100 PENNSYLVANIA AVENUE, N.W., SUITE 800, WASHINGTON, DC, 20037, US

(73) Assignee: Weidmann Plastics Technology AG, Rapperswil (CH)

(21) Appl. No.: 10/535,819

(22) PCT Filed: Nov. 20, 2003
(86) PCT No.: PCT/CH03/00766

§ 371 Date: May 16, 2006

(30) Foreign Application Priority Data
Nov. 20, 2002 (CH) 1943/02

(51) Int. Cl. H01L 21/30

(52) U.S. Cl. 438/455

(57) ABSTRACT

The invention relates to a method for producing a component, comprising a body (1), to which pressure-sensitive adhesive is applied, at least in sections. To produce the component (10, 20, 30), a pressure-sensitive adhesive base (6) is applied to the body (1). Said applied pressure-adhesive base (6) is at least partially cross-linked until it achieves a predetermined viscosity. The pressure-sensitive adhesive base (6) is preferably applied directly to the body (1). The component is cost-effective to produce, can be simply mounted and is extremely strong.

The invention relates to a method for producing a component having a body on which at least in regions a pressure-sensitive adhesive is disposed. The invention also relates to a body for producing a component of this type, and to a component produced according to said method.

Components in industry and handicraft are increasingly being fastened by adhesive bonding. By this means it is possible in automobile construction, for example, to mount plastic parts very easily and conveniently. The components are adhesively bonded using pressure-sensitive adhesive diecuts, adhesive transfer tapes, and adhesive tapes provided double-sidedly with a pressure-sensitive adhesive. Pressure-sensitive adhesive tapes of this kind for technologically demanding joining tasks must be produced with a very high-grade pressure-sensitive adhesive; only tapes of that kind achieve sufficient bond strengths. Their production, however, is very complex and takes place on large-scale, inflexible plants, that are generally expensive, in mass production, one of the reasons for which is the need to operate in the absence of oxygen. These pressure-sensitive adhesives (PSAs) are substances which remain permanently tacky and adhesive. Under a gentle applied pressure they attach immediately to almost all surfaces. The state of the art in the field of pressure-sensitive adhesion is shown for example in I. Benedek, L. J. Heymans, “Pressure Sensitive Adhesive Technology”, Marcel Decker Inc., 1st edition 1997. Base polymers of modern PSAs are predominantly polyacrylates, natural and synthetic rubbers, polyesters, polychloroprene, polyisobutenes, polyvinyl ethers, polyurethanes, and polysiloxanes, which are used together with additives, such as resins, plasticizers, fillers, and stabilizers, for example.

The application of adhesive tapes to a body is comparatively complex. The adhesive tapes must be cut to size and, in general aligned precisely; in the case of diecuts there is no need to cut to size, but increased complexity arising in production makes the production process more expensive, while the mounting complexity remains.. In the case of complex bodies, and particularly three-dimensional bodies, with an uneven outer surface, the application of adhesive tapes or adhesive-tape diecuts is very difficult or usually even impossible. Elevations and indentations in particular, and also narrow edges, cannot be masked with adhesive tapes. In such cases it is necessary for the component to be attached, for example, by screwing or snap-locking, for example, as has hitherto been customary. The problem exists that such components cannot rationally be joined with pressure-sensitive adhesives as part of a modern manufacturing operation.

Even in the case of simple planar components there is a problem that a great amount of time can be lost in removing the liner, which for reasons associated with the manufacturing operation does not project beyond the area of adhesion. In the case of mounting tasks employed to date it is necessary, for time-critical tasks (production cycle), to provide a gripping aid for removal of the liner, this being very expensive, since it has primarily to take place by hand.

On the one hand, known pressure-sensitive systems cannot be used, for the reasons stated; on the other hand, the known production technologies are incapable of reacting with sufficient flexibility to the requirements involved in small-scale manufacturing, to make available to the user the respectively suitable pressure-sensitive adhesive at an acceptable price.

WO 00/44807 discloses a single-component epoxy resin adhesive which has been elasticated with silicone rubber and whose open-joint time can be adapted. The open-joint time is the time within which the adhesive remains liquid. In the present case it is about 1 to 3 hours. To give an adhesive bond the maximum strength a thermal postcure is performed. Workpieces can be pre-fixed with an epoxy resin adhesive of this kind, and require no additional support during the thermal post-cure. Epoxy resin adhesives possess an ultimate strength, which in this case must be achieved by postcuring, and so are not part of the group of the permanently tacky pressure-sensitive adhesives, which can be joined, or joined again, at a later time. The object on which the invention is based is to provide a method of the type stated which allows easier and more cost-effective production of components which have, at least in regions, a pressure-sensitive adhesive segment and can be mounted by adhesive bonding. The method ought also to allow the production of components having an uneven surface. The pressure-sensitive adhesive ought, moreover, to possess a comparatively high strength.

This object is achieved with a method according to claim 1. In the method of the invention a pressure-sensitive adhesive base is applied to the body. Before the pressure-sensitive adhesive base is applied, the surface of the body can be modified by means of a surface treatment (e.g., flaming, corona treatment, plasma treatment, etc.) for the purpose of improved adhesion. Said pressure-sensitive adhesive base generally possesses a low viscosity and can be applied, for example, using a slot die or by spraying. In this case it is also possible to coat uneven surfaces, indentations for example, or projections, with a pressure-sensitive adhesive base of this kind. Because of the comparatively low viscosity the pressure-sensitive adhesive base is also able to penetrate indentations and to wet the surface of the material effectively. After the pressure-sensitive adhesive base has been applied it is crosslinked until a predetermined viscosity is reached. Crosslinking takes place, for example, by irradiation or by heating. After the defined partial or complete crosslinking the body is provided with a precisely contoured adhesive layer or with an adhesive film which possesses a comparatively high mechanical stability and/or, if appropriate, is also plastically deformable. The component can then be mounted with ease, by placing it under gentle applied pressure onto the envisaged part. Further fixing means are not generally necessary, but may readily be provided. A fixing operation of this kind can generally be automated. The application of the pressure-sensitive adhesive base as well, and the crosslinking, can be automated. The method is therefore suitable for both small-scale and large-scale runs. In a flexible operation in respect of pressure-sensitive adhesive selection and application it is possible in accordance with the invention to forgo many conventional processing steps in PSA tape or diecut production, which are reflected in the manufacturing costs, while retaining various degrees of freedom for the user.

According to one development of the invention the pressure-sensitive adhesive base is applied directly to the body. This is done, for example, using a controllable slot die or by punctiform application by means of a piezoelectric nozzle.

According to one development of the invention it is envisaged that the pressure-sensitive adhesive base is crosslinked through a protective film (liner). A protective film of this kind is preferably transparent. After crosslinking, or part-crosslinking, the pressure-sensitive adhesive is protected against soiling or else through chemical exposures—for example, against oxidation. For mounting, the film is then peeled off. The protective film may contact the adhesive film partially, over its full area or not at all. The cavity between the film and the adhesive may have been filled with inert gas (e.g., carbon dioxide or nitrogen). This is especially important when a further crosslinking reaction can take place only in the absence of oxygen. The protective film may be self-adhesive partially or over-.its full area, or may be fastened to the component using an adhesive tape.

According to a development of the invention it is envisaged that the pressure-sensitive adhesive base is applied punctiformly or sectorially. The individual points or sectors, respectively, may be formed by different pressure-sensitive adhesives or by combinations of pressure-sensitive adhesive and conventional adhesives. As a result it is possible to achieve a particularly high strength and/or adhesion under applied pressure, which as a result can be developed and adapted specifically for each component. The pressure-sensitive adhesives may, for example, have different physical/technological properties and different geometric dimensions.

According to a development of the invention it is envisaged that the pressure-sensitive adhesive base is applied with a liner to the body. The liner is composed preferably of a film and a layer of the pressure-sensitive adhesive base. After the liner has been applied, crosslinking can take place through the film. In this case the film may also at the same time be a support for the pressure-sensitive adhesive base and, after crosslinking, a protection against soiling and chemical exposure. Prior to mounting, the film is peeled off.

According to a development of the invention the liner is permanently multidimensionally deformed. The deformation is modeled on the surface to which the liner is applied. The deformation of the liner can take place, for example, by thermoforming. The application of the pressure-sensitive adhesive base to the liner may likewise be punctiform or sectorial. Here too it is possible to employ different pressure-sensitive adhesives or to employ pressure-sensitive adhesives in combination with conventional adhesives. Preference is given to using a liner possessing a surface whose adhesiveness is low. This makes it easy to peel off the film following application or crosslinking of the pressure-sensitive adhesive base on the body.

Further advantageous features arise from the dependent claims, the subsequent description, and the drawing.

Exemplary embodiments of the invention are elucidated below with reference to the drawing. In this drawing:

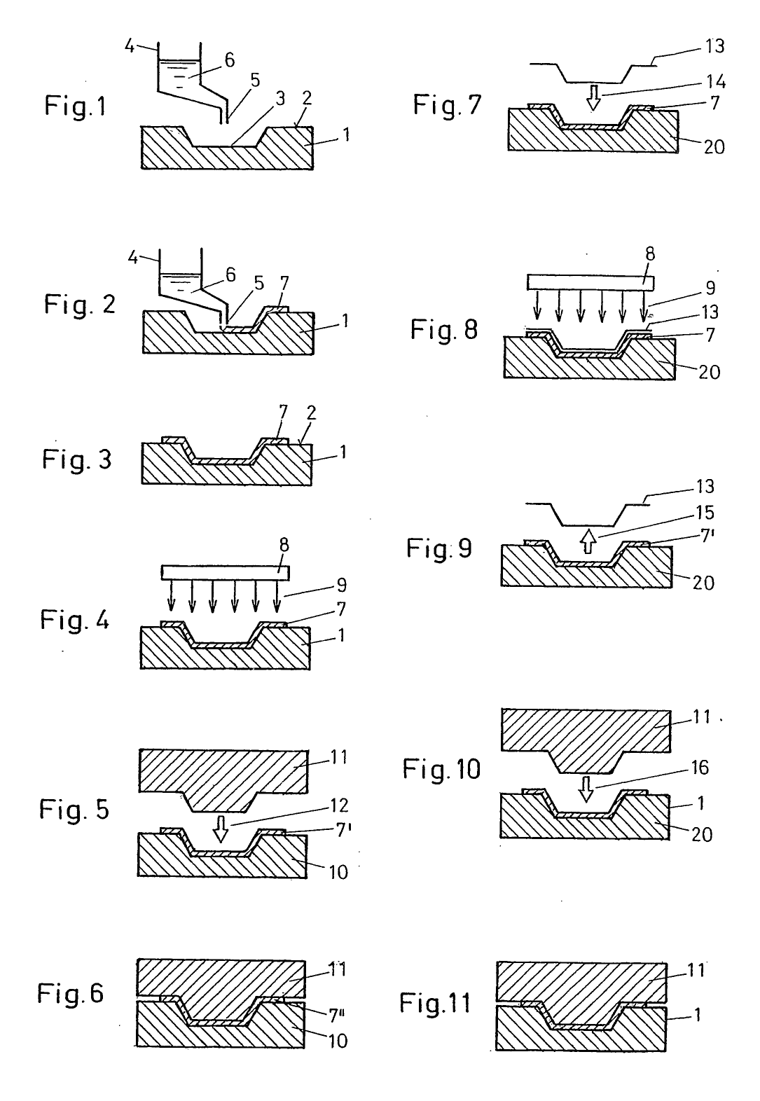

FIGS. 1-6 show, diagrammatically, individual steps in the method of the invention,

FIGS. 7-11 show diagrammatic steps of a method of the invention according to one variant,

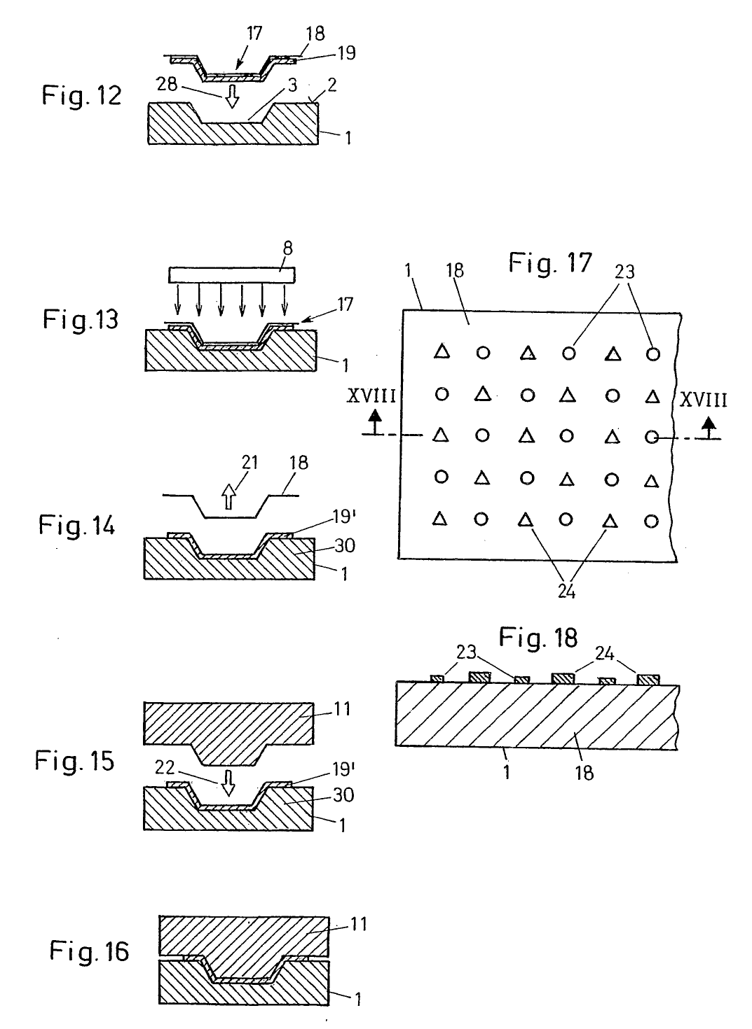

FIGS. 12-16 show, schematically, individual steps in a method of the invention according to another variant,

FIG. 17 shows, diagrammatically, a plan view of a liner or body, and

FIG. 18 shows a section along the line XVIII-XVIII of FIG. 17.

FIG. 1 shows a body 1, an injection molding by way of example, with a top face 2 possessing an indentation 3. The body 1 is to be provided in the region of the indentation with an attachment film for the purpose of its fastening to a part 11 (FIG. 5). For this purpose, in accordance with FIG. 2, a layer 7 is applied using a slot die 5. The die 5 is provided with a vessel 4 in which there is a pressure-sensitive adhesive base 6. This pressure-sensitive adhesive base 6 is applied uniformly, preferably in a controlled fashion, using the slot die 5, and this layer 7 is adapted in precisely contoured fashion to the indentation. The slot die 5 can also be replaced by another apparatus for applying the pressure-sensitive adhesive base 6; for example, the pressure-sensitive adhesive base 6 can be applied to the top face 2 by spraying or by application of drops. Also possible is a partial, sectorial or punctiform application, which is elucidated in more detail later on below.

The pressure-sensitive adhesive base 6 may comprise one or more additives. The additives are, by way of example, fillers, adhesion promoters or plasticizers. One suitable additive comprises, for example, hollow glass beads. The pressure-sensitive adhesive base 6 can also have been foamed and can also be foamed shortly before or after application or not until after bonding. Prior to application, the surface of the body 1 can be modified for the purpose of improving adhesion. Particularly suitable for this purpose is an operation of flaming or a corona or plasma treatment.

FIG. 3 shows the applied layer 7. This layer may also extend over the entire top face 2 and also over the other narrow sides and broad sides of the body 1.

The pressure-sensitive adhesive base 6 is preferably a prepolymer capable of pressure-sensitive adhesion. The pressure-sensitive adhesive base may be a reactively diluted system with a UV initiator and/or thermally blocked free-radical initiators. Also possible, however, are solvent-based systems and hotmelt PSAs, which may likewise include further crosslinking capacities. Suitable polymers include, in particular, acrylates, SIS/SBS PSAS, polyurethane PSAS, and silicone PSAs. In each case, however, the adhesives are preferably PSA polymers or PSA prepolymers which are in an uncrosslinked or only partly crosslinked state.

Following application, the layer 7, in accordance with FIG. 4, is crosslinked. Crosslinking takes place, for example, using apparatus 8 which emits UV, VIS, IR or electromagnetic radiation or electron beams 9. It is also possible here to conceive of any other method for introducing energy into the layer 7, though. For example, crosslinking can be carried out with heat or chemically. For chemical crosslinking, one-component and multicomponent systems are known per se, it also being possible for the second component to have been incorporated into the system by means of microcapsules. Preferably the crosslinking reaction is initiated by means of UV radiation. Further crosslinking, until the desired properties have been achieved, can then take place without irradiation and hence “in shadow”.

The pressure-sensitive base 6 may have been furnished with an additive. Said additive is, in particular, a filler, a plasticizer or a tackifier, which is produced, for example, from a resin and which increases the tack. Additives, moreover, may have been provided which reduce or prevent external influences, such as a possible oxygen inhibition, during the crosslinking reaction. The additives may comprise hollow glass beads, or glass beads. The pressure-sensitive adhesive base may have been foamed or may be foamed at any desired time. After crosslinking, the pressure-sensitive adhesive base may be plastically deformable. The pressure-sensitive adhesive base 6 can be crosslinked according to a one-component system or multicomponent system.

During the crosslinking of the layer 7 the molecular weight is increased. By crosslinking here is also meant a chain extension. The crosslinking or chain extension produces an increase in the viscosity in accordance, for example, with the Dalquist criterion. There are also other suitable viscosity standards here. The crosslinked or part-crosslinked layer 7, in accordance with FIG. 5, is preferably plastically deformable. The viscosity is adjusted so that the tendency of the layer 7′ to creep is low. After the crosslinking of the layer 7, the component 10 is already in mountable condition. In order to join said component 10 to a part 11, all that is needed is a comparatively low applied pressure in the direction of the arrow 12. Following placement, the component 10, owing to the high strength of the layer 7′, is already self-supporting. Generally speaking, therefore, there is no need for the component 10 to be supported or otherwise fastened to the part 11. After the component 10 has been joined, the layer 7′ can be crosslinked further and may form a fully crosslinked layer 7″. Further crosslinking may also be accelerated, for example, by radiation or by heating. Even after this crosslinking, the polymer remains pressure-sensitively adhesive. Said further crosslinking is not mandatory. Sufficient adhesive strength is preferably achieved in the first crosslinking reaction.

In the case of the variant in accordance with FIGS. 7 to 11 it is possible, after the application of the layer 7, in the direction of the arrow 14, to apply a protective film 13. This protective layer 13 can preferably be transparent or part-transparent in design, so that in accordance with FIG. 8 it is possible for crosslinking to take place through said film 13. In this case as well a known crosslinking variant is conceivable, including radiation 9 or heat exposure. The advantage of this method is that the layer, at least after crosslinking, is protected against soiling and chemical exposure. Preferably the film 13 is impervious to air and/or gas. The film 13 may also protect the layer 7 prior to crosslinking. In this way it is possible for coated parts to be held in stock prior to crosslinking. The protective film 13 may be of a design such that it contacts the adhesive over the full area, partially or not at all. Any cavities between the protective film 13 and the adhesive can have been filled with inert gas. The protective film 13, moreover, may have been produced from an adhesive of comparatively low adhesion.

After crosslinking, the film 13 can be left on the body for a relatively long time, for the storage of the coated body 20, for example. For mounting, the film 13 is peeled off, in accordance with FIG. 9. In this case the crosslinked layer 7′ remains on the body 1. The film 13 is produced from a material, or coated with a material, to which the pressure-sensitive adhesive base and also the crosslinked pressure-sensitive adhesive adheres to a lesser extent than to the body 1. After the film 13 has been peeled off, the component 20′ can be joined as outlined above.

In the case of the method in accordance with FIGS. 12 to 16, the pressure-sensitive adhesive base is applied with a support 17 to the body 1. The support 17 is composed of a liner 18, which by way of example is a film, and a layer 19 of the pressure-sensitive adhesive base. The layer 19 may likewise be applied with a slot die to the liner 18. Also conceivable here, however, is application by spraying, knife coating or in the form of drops. For application in the form of drops a suitable method, for example, is a contactless method, using a so-called Bubble-Jet or Delo-Dot, for example.

FIGS. 17 and 18 show a version of the liner 18 in which the pressure-sensitive adhesive base has been applied punctiformly. Provided in this case are different punctiform application regions 23 and 24. These regions 23 and 24 are formed by different pressure-sensitive adhesive bases or by a pressure-sensitive adhesive in combination with conventional adhesives. The application regions 23 and 24 may therefore have different physical/technological properties and different geometrical dimensions. For example, the thickness, in accordance with FIG. 18, may be different. The thickness is situated for example in the range from 10 to 4000 micrometers, preferably in the range from 300 to 1000 micrometers. In this case the regions 23 are less thick than the regions 24. Alternatively or at the same time, the regions 23 and 24 may be formed by different pressure-sensitive adhesives. For example, the pressure-sensitive adhesive base of the regions 24 may have a higher viscosity than the pressure-sensitive adhesive base of the regions 23; the chemical degree of crosslinking, the chemical crosslinking potential, the adhesion promoters, the heat resistance or other technological properties may vary. Also conceivable here, however, is another punctiform region and/or a sectorial application. By way of example, the regions 23 and 24 may be in the form of stripes, may be circular or may be wavy. The method comprises the advantage of being able to adapt the properties and the appearance of the areas of adhesive ideally to the requirements of the component and of the adhesive bond, in a way which is not possible with conventional joining methods or mounting techniques.

The support 17 is preferably shaped in correspondence to the surface 2 and/or to the indentation 3. The support 17 preferably is permanently deformed. The support 17 can be deformed, for example, by thermoforming. This thermoforming is possible before or after the application of the layer 19. The liner 18, moreover, can be produced by injection molding with the intended three-dimensional shape. The liner 18 is composed, for example, of plastic. Also conceivable, however, is a version made of metal, aluminum for example.

The liner may be in web form and film form and may be 3D-shaped in situ. The support 17, in accordance with FIG. 12, is placed in the direction of the arrow 28 onto the body 1, preferably under gentle applied pressure. This is preferably done in an automated procedure. Since with this method the liner protrudes beyond the adhesive regions, or does not end flush with the borders of the component, the subsequent attachment of an expensive peel-removal aid on the liner of the adhesive tape is no longer necessary here.

After the support 17 has been placed, the pressure-sensitive adhesive base of the layer 19 is crosslinked, which, in accordance with FIG. 13, can take place with radiation 9 or with other means, as already stated above. Precrosslinking may also take place before the liner is placed.

After crosslinking, the crosslinked layer 19′ is protected by the liner 18 against soiling and chemical exposure. Accordingly a component 30 has been produced, and can be put into stock or mounted immediately. For mounting, in accordance with FIG. 14, the liner 18 is peeled from the layer 19′ in the direction of the arrow 21. This too can take place in an automated procedure. Finally, the joining operation is carried out, in accordance with FIGS. 15 and 16.

The component 10, 20 or 30 is in particular a component for automobile construction, although other components are also possible, examples being housings or housing parts for appliances, sanitary appliances for example. For such a component the pressure-sensitive adhesive base 6, after the body 1 and the part 11 have been joined, can also fulfill the function of a seal. Any multidimensional bodies which can be joined inexpensively with pressure-sensitive adhesives using this method are conceivable. The components 10, 20 and 30 are preferably ready for mounting, transportable and also storable. The production process may take place with full or partial automation.

The pressure-sensitive adhesive layer which is applied to the component or the liner may be of single-layer or multilayer form. Versions conceivable include, for example, an adhesion promoter layer on the component or an outer layer on the adhesive film which increases the adhesion to the surface to be bonded (e.g., automobile finish). The application methods for the individual layers, the layer thicknesses, and the crosslinking may be identical or different. In particular, the adhesive layers may be crosslinked simultaneously after entire application, or in stages after partial coatings. One or more layers may be foamed.

### LIST OF REFERENCE NUMERALS

1 body
2 top face
3 indentation
4 vessel
5 slot die
6 pressure-sensitive adhesive base
7 layer
8 crosslinking apparatus
9 radiation source
10 component, ready for mounting
11 part
12 arrow (direction of force for joining)
13 protective film and line
14 arrow (direction of force, liner application)
17 support
18 liner
19 layer of pressure-sensitive adhesive base
20 coated body
21 arrow, liner removal
23 application region with pressure-sensitive adhesive a
24 application region with pressure-sensitive adhesive b
28 arrow
30 component

1. A method for producing a component (10, 20, 30) having a body (1) on which at least in regions a pressure-sensitive adhesive is disposed, characterized by the following steps:
a) providing a body (1) and a pressure-sensitive adhesive base (6),
b) applying the pressure-sensitive adhesive base (6) to the body (1) and
c) at least partly altering the pressure-sensitive adhesive base (6) until the predetermined profile of properties is acquired.

2. The method of claim 1, characterized in that the pressure-sensitive adhesive base (6) is at least partly crosslinked until a predetermined viscosity is acquired.

3. The method of claim 1, characterized in that the pressure-sensitive adhesive base (6) is applied directly to the body (1).

4. The method of claim 1, characterized in that the pressure-sensitive adhesive base (6) is applied to the body (1) by means of a liner (18).

5. The method of claim 1, characterized in that the adhesive layer is of single-layer or multilayer construction.

6. The method of claim 1, characterized in that the adhesive layer(s) are applied and/or crosslinked at one time or in stages, with different crosslinking reactions being combined with one another.

7. The method of claim 1, characterized in that the pressure-sensitive adhesive base (6) is applied to the body (1) by means of a slot die (5).

8. The method of claim 1, characterized in that the pressure-sensitive adhesive base (6) is applied to the body (1) by spraying.

9 The method of claim 1, characterized in that the pressure-sensitive adhesive base (6) is applied by application of drops.

10. The method of one of claims 1 to 9, characterized in that the pressure-sensitive adhesive base (6) is precrosslinked prior to application.

11. The method of one of claims 1 to 10, characterized in that the applied pressure-sensitive adhesive base (6) is crosslinked by radiation.

12. The method of claim 11, characterized in that the applied adhesive base (6) is activated by radiation and in that further crosslinking reaction proceeds without irradiation.

13. The method of claim 11, characterized in that the pressure-sensitive adhesive base (6) is cross-linked by UV, VIS, IR or other electromagnetic radiation or electron beams.

14. The method of one of claims 1 to 10, characterized in that the pressure-sensitive base (6) is crosslinked chemically.

15. The method of claim 14, characterized in that the pressure-sensitive adhesive base is crosslinked according to a one-component or multicomponent system.

16. The method of one of claims 1 to 15, characterized in that the pressure-sensitive adhesive base (6) after crosslinking is plastically deformable.

17. The method of one of claims 1 to 16, characterized in that the pressure-sensitive adhesive base (6) has been provided with an additive.

18. The method of claim 17, characterized in that the additive is a filler.

19. The method of claim 17, characterized in that the additive is a plasticizer or tackifier.

20. The method of claim 17, characterized in that the additives reduce or prevent external influences, such as a possible oxygen inhibition, during the crosslinking reaction.

21. The method of claim 17, characterized in that the additive comprises glass beads.

22. The method of one of claims 1 to 21, characterized in that the pressure-sensitive adhesive base (6) has been foamed or is foamed at any desired time.

23. The method of one of claims 1 to 22, characterized in that the applied pressure-sensitive adhesive base (6) is lined with a protective film (13, 18), the protective film being shaped according to the contour of the body.

24. The method of claim 1 to 23, characterized in that the protective film contacts the body over the full area, partially or not at all.

25. The method of claim 1 to 24, characterized in that the cavities there may be between the protective film and the adhesive have been filled with inert gas.

26. The method of claim 23, characterized in that the protective film (13, 18) is transparent or part-transparent.

27. The method of claim 23, characterized in that the pressure-sensitive adhesive base (6) is cross-linked through the-protective film (13,18).

28. The method of one of claims 4 and 23 to 27, characterized in that the protective film (13, 18) is produced from a material having comparatively low adhesion, or has been coated.

29. The method of claim 4, characterized in that the liner (18) is shaped at least in regions to the precise contour of an area (2) of the body (1).

30. The method of claim 29, characterized in that the liner (18) has been thermoformed.

31. The method of claim 4, characterized in that the liner (18) has been multidimensionally preshaped.

32. The method of claim 4, characterized in that the liner (18) has been or is permanently multi-dimensionally deformed.

33. The method of claim 4, characterized in that the liner (18) is deformed thermally.

34. The method of claim 4, characterized in that the pressure-sensitive adhesive base (6) is disposed substantially uniformly on the liner (18).

35. The method of claim 4, characterized in that the pressure-sensitive adhesive base (6) is disposed partially or sectorially on the liner (18).

36. The method of claim 35, characterized in that the pressure-sensitive adhesive base (6) is disposed punctiformly or linearly on the liner (18).

37. The method of one of claims 1 to 36, characterized in that to the body (1) or to a support (17) there are applied two or more different pressure-sensitive adhesive regions (23, 24) or a combination of at least one pressure-sensitive adhesive and conventional adhesive.

38. The method of claim 1, characterized in that the application of the pressure-sensitive adhesive base takes place discontinuously.

39. The method of one of claims 1 to 38, characterized in that the surface of the body (1) at least in regions, prior to the application of the pressure-sensitive adhesive base, is modified for improved adhesion, especially by flaming, corona treatment or plasma treatment.

40. A body for producing a component, characterized in that on said body at least in regions a pressure-sensitive adhesive base is disposed which for the purpose of acquiring predetermined properties is to be at least partially and/or regionally altered, and in particular is to be altered, and in particular is to be crosslinked.

41. The body of claim 40, characterized in that the pressure-sensitive adhesive base is a prepolymer capable of pressure-sensitive adhesion.

42. The body of claim 40 or 41, characterized in that the pressure-sensitive adhesive base is disposed in an indentation in the body.

43. A component produced from a body according to one of claims 40 to 42, characterized in that the pressure-sensitive adhesive has been crosslinked until a predetermined viscosity is acquired.

44. The component of claim 43, characterized in that the attachment layer has been lined with a liner.

45. The component of-claim 40 to 44, characterized in that, after the body (1) and the part (11) have been joined, the pressure-sensitive adhesive base (6) also fulfills the function of a seal.
